(19) United States
(12) Patent Application Publication
(10) Pub. No.: US 2024/0271270 A1
(43) Pub. Date: Aug. 15, 2024

(54) CONDUCTIVE SILICON SPUTTERING TARGETS

(71) Applicants: SOLERAS ADVANCED COATINGS BV, Deinze (BE); SOLERAS ADVANCED COATINGS (JIANGYIN) CO. LTD, Jiangyin City Wuxi, Jiangsu (CN)

(72) Inventors: Wilmert DE BOSSCHER, Drongen (BE); Ignacio CARETTI GIANGASPRO, Antwerpen (BE); Yuping LIN, Anhui (CN)

(21) Appl. No.: 18/567,451

(22) PCT Filed: Jul. 15, 2022
(86) PCT No.: PCT/EP2022/069827

§ 371 Date: Dec. 6, 2023

(30) Foreign Application Priority Data
Jul. 16, 2021 (BE) 2021/5550

(51) Int. Cl. C23C 14/34; C23C 14/00; C23C 14/14

(52) U.S. Cl. CPC C23C 14/3414; C23C 14/0036; C23C 14/14

(57) ABSTRACT

A target for sputtering having target material for sputtering includes a lamellar structure and a porosity of at least 1% and having a resistivity lower than 1000 ohm·cm and further includes silicon and at least a further element from the group 13 and/or the group 15 of the periodic table. The amount of silicon is at least 98 wt. %, and the amount of the at least a further element is higher than 0.001 wt. % and lower than 0.03 wt. %. The amount does not include the amount of nitrogen if present. A manufacturing method and a sputtering method are also provided.

### FIELD OF THE INVENTION

The present invention relates to the field of silicon sputter targets. More specifically it relates to conductive silicon sputter targets and method of production thereof, and a sputtering method.

### BACKGROUND OF THE INVENTION

The technique of material deposition by means of sputtering is known already for many decades. Typically, a plasma is generated in a low pressure chamber in which an inert gas such as argon, or an active gas such as oxygen or nitrogen is present, and a high negative voltage is applied on a so-called “sputter target” (containing the material to be deposited). The gas atoms can be ionized, and the sputter target is bombarded by the positive gas ions, so that atoms are freed from the sputter target, and move to the “substrate”, where they are deposited.

Three kinds of power source can be identified: DC power, AC or pulsed power (in the range of kHz, e.g. at a frequency of 1 to 100 kHz) and RF power (in the range of MHz, e.g. at a frequency of 0.3 to 100 MHz). Thus, the sputtering can be classified as DC-, AC- or RF-sputtering. DC power is typically used when the sputter target contains an electrically conductive sputter material, and the deposited layer has some degree of conductivity as well. AC power is typically used when the deposited layer has low conductivity, or it is dielectric. RF power is typically used when the sputter target has low electrical conductivity or is insulating. While using RF, the sputter rate for same power levels is typically significantly lower than a DC process and the cost per watt for the electronics is usually higher for RF power supplies.

Sputtering of Si targets is common practice and being used in many applications. Especially sputtering from a Si target in a reactive gas ambient is well known for many optical applications. These include silicon nitride deposition for architectural glass, for which high refractive index layers can be provided, or silicon dioxide deposition within optical stacks on rigid and flexible transparent substrates, providing a low refractive index material layer for generating optical interference with other layers of the stack.

Pure Si targets are fully insulating unless they contain a certain type and level of impurities or doping, which is crucial to define the conductivity of the material and facilitate the sputtering process. However, the presence of these impurities may negatively affect the deposition rate and properties of the deposited layers. A high deposition rate is often required in thin film manufacturing to i) achieve high production throughputs by allowing a high line speed of the coater used for sputtering or ii) reduce energy consumption by allowing lower sputtering powers.

For silicon nitride deposition, usually Si targets comprising between 2 and 20 wt. % Al are sputtered in an environment comprising nitrogen gas. Because of the insulating nature of the deposited layer, typically AC sputtering is used. The addition of Al helps increasing the target conductivity and process stability while the optical properties of the layers still comply with the requirements, as AlN has a high refractive index. However, the deposition rate may be reduced due to compound formation of the aluminium in the target.

Usually, silicon dioxide deposition is provided with Si targets, allowing a very low refractive index. The deposition rate of silicon dioxide is typically much lower than that of silicon nitride. Si targets with up to 10 wt. % Al doping are also used in certain applications for sputtering SiO₂ thin films. However, adding Al to the target to increase its conductivity can be detrimental to the deposition rate and the optical properties, since the formed Al₂O₃ has a significantly lower sputter rate and will increase the refractive index of the deposited layer.

It would be thus desirable to provide a silicon target with the advantages of pure silicon targets, but with effective and stable deposition provided by conductive targets, and high deposition rates.

### SUMMARY OF THE INVENTION

It is an object of the present invention to provide good sputtering and good sputtering targets, and methods for producing the same, which allows providing layers including silicon with effective sputtering and high deposition rate.

The above objective is accomplished by methods and device in accordance with the present invention.

The present invention provides a sputter target with target material for sputtering which comprises a lamellar structure and a porosity of at least 1%. It has a resistivity below 1000 ohm·cm, more preferably below 100 ohm·cm, e.g. such as below 10 ohm·cm. The target material includes silicon at an amount of at least 98 wt. %, more preferably at least 99 wt. %, e.g. such as higher than 99.5 wt. %. It also includes at least a further element from the group 13 and/or the group 15 of the periodic table, wherein the amount of the at least a further element is lower than 0.03 wt. % but higher than 0.001 wt. %. It is an advantage of embodiments of the present invention that a silicon layer can be provided with dopants from the group 13 or 15, without negatively affecting the deposition rate or the optical properties. Said amount does not include the amount of nitrogen, if nitrogen is present.

It is an advantage of embodiments of the present invention that a high target sputter rate and a stable sputtering can be obtained for silicon oxide or silicon nitride layers, in AC or even DC sputtering, where no RF sputtering is required. It is an advantage that optical layers with tailored optical index can be provided with high deposition rate and effective use of sputter power.

The inventors found that a composition of the target material as described above allows for a target resistivity that is not too high, thus allowing sputtering in frequencies lower than RF, such as MF AC, even DC, e.g. pulsed DC, while also having a target resistivity that is not too low. It was surprisingly found that the resulting target resistivity allowed for sputtering in such frequencies (e.g. in DC) while also resulting in a good stability of the sputter process over time, avoiding arcing and other instabilities in the sputtering process.

The at least a further element comprises an element from the group 13 of the periodic table, thus a p-type dopant. For example, that element may be boron.

It is an advantage of embodiments of the present invention that a silicon layer with p-type doping can be provided with dopants from the group 13 in a fast, stable way.

In some embodiments, the target may include oxygen and/or nitrogen in an amount lower than 0.5 wt. %.

In some embodiments, the target material comprises or consists of a single piece of target material for sputtering with a length of at least 500 mm, for example at least 800 mm.

It is an advantage of embodiments of the present invention that a single piece can be provided, with using less or without using tiles, thus reducing the effects such as arcing from, or erosion of, the edges of tiles.

In some embodiments, the target comprises a thickness of at least 4 mm of material for sputtering. It is an advantage of embodiments of the present invention that a large volume of layers can be provided with a single target, being a durable and resilient target thanks to the lamellar structure.

In some embodiments, the target is a cylindrical target.

It is an advantage of embodiments of the present invention that the target can withstand sputtering at a power density higher than 30 kW AC/m, e.g. 35 kW AC/m or higher, such as 40 and even higher than 50 kW AC/m without delamination, cracking or generating any other material defect.

In a further aspect, the present invention provides a method for sputtering using a target of the previous aspect of the present invention, comprising providing the target of the present invention and providing sputtering using the target for depositing a layer comprising silicon at a power density higher than 30 kW/m, e.g. 35 kW/m or higher, such as 40 kW/m and even higher than 50 kW/m, in AC or DC sputtering.

In some embodiments, the method is adapted to provide sputtering in a non-reactive atmosphere or in a reactive atmosphere comprising oxygen and/or nitrogen.

In some embodiments, the working pressure during sputtering in the sputtering or deposition chamber is in the range between 0.1 Pa and 10 Pa.

In a further aspect, the present invention provides a manufacturing method for manufacturing a target, for example a target in accordance with embodiments of the first aspect of the present invention. The method comprises:
providing silicon in sprayable form,
proving at least a further element from the group 13 or the group 15 of the periodic table in sprayable form,
providing a backing substrate, and
spraying the silicon and the at least further element on the backing substrate in amounts, and with sputtering parameters, configured such that a target is formed with a porosity of at least 1%, and including at least 98 wt. %, more preferably at least 99 wt. % or even higher than 99.5 wt. % of silicon and more than 0.001 wt. % but less than 0.03 wt. % of at least a further element from the group 13 or the group 15 of the periodic table. The amount of the at least further element excludes the amount of nitrogen, if present.

It is an advantage of embodiments of the present invention that a target can be obtained by spraying, with very accurate control on the concentration of dopants, for providing a target with high sputter rate and relatively high conductivity for stable AC or DC sputtering.

In some embodiments, the spraying is done by thermal spraying, e.g. plasma spraying.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 illustrates a target in accordance with embodiments of the present invention.

FIG. 2 illustrates a comparative graph showing different dynamic deposition rates for existing targets and for targets in accordance with embodiments of the present invention, as a function of the oxygen flow rate during sputtering.

FIG. 3 illustrates a detail of the graph in FIG. 2 indicated with the dashed rectangle 200.

FIG. 4 illustrates a comparative graph showing different dynamic deposition rates for existing targets and for targets in accordance with embodiments of the present invention, as a function of the nitrogen flow rate during sputtering.

FIG. 5 illustrates a scheme of a method to sputter a target in accordance with embodiments of the present invention.

FIG. 6 illustrates a scheme of a method of manufacturing a target in accordance with embodiments of the present invention.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings, but the invention is not limited thereto but only by the claims. The dimensions and the relative dimensions do not correspond to actual reductions to practice of the invention.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B; but it can, however, also encompass devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is to be understood that embodiments of the invention may be practiced without these specific details. In other instances, well-known methods, structures and techniques have not been shown in detail in order not to obscure an understanding of this description.

Where in embodiments of the present invention reference is made to sputter rate and to deposition rate, reference is made to the flux density of material leaving the target, respectively to the flux density of material arriving to the substrate.

Silicon is widely used as part of coatings, and it is part of a wide range of applications, from microelectronics to architectural structures. However, pure silicon is not a good electrical conductor, which leads to resistive power loss over the target material when electric current passes through. Some applications demand the presence of other materials, such as oxygen or nitrogen, in the layer. These can be provided via reactive sputtering, by sputtering in an environment including oxygen or nitrogen depending on the requirement. However, these gases and their amounts also affect the sputtering process. The sputter rate varies depending on the flow of gas, and the gas may react with the target material while still in the target.

The present invention allows providing a highly pure Si target material product with low doping and impurity levels, while maintaining good electrical conductivity for stable sputtering in DC or AC (for example, under 500 kHz) mode.

The target material product has lamellar structure, for example it consists of a lamellar structure formed by overlapping splats, e.g. obtained by the production method of thermal spraying, and the amount of silicon in the target material is at least 98%, for example 99% or higher than 99.5 wt. %, but it is doped with at least one doping material with less than 0.03 wt. %, as specified below.

In particular, the Si target material product is doped with one or more elements from the group 13 or 15 of the periodic table, or a combination thereof. The amount of group 13 or group 15 dopant in the target material, excluding nitrogen, is lower than 0.03 wt. %. These targets present a lamellar, splat-like microstructure, due to the method of manufacture by spraying. As such, these targets exhibit some limited porosity as well. It has been observed that a combination of these properties allows for sputtering Si compound layers in a more effective and stable manner at a higher achievable deposition rate and sputter power density compared to state-of-the-art Si target materials; even in DC or AC mode while a sufficiently high electrical conductivity may be maintained.

In a first aspect, the present invention provides a sputter target including target material for sputtering with lamellar structure, for example provided by spraying. The material for sputtering may be provided over a carrier, e.g. on a bondcoat on the carrier. The target may comprise at least 4 mm of material for sputtering.

Silicon as material for sputtering presents high internal stress, limiting the available thickness of the target material. As the silicon thickness increases, so does the stress, which may result in cracking or delamination of the target material. This is particularly true when the silicon target material is subjected to high power densities during sputtering. The target material for sputtering of the present invention presents lamellar structure, formed by overlapping splats of sprayed material. Thanks to the lamellar structure and the degree of porosity, resilient targets can be provided with a high thickness, e.g. larger than 4 mm, such as 6 mm or even 9 mm and beyond, without cracking phenomena and the like.

Moreover, although the concentration of dopant is relatively low, the conductivity is good enough to provide low electric losses and good enough thermal conductivity, allowing a more effective use of the power and a higher power density, as there is less risk of thermal overload and fracture. Thus, it is possible to benefit from the whole service lifetime, as there is low chance of cracking, and with an efficient use of energy (better utilization of the power due to the low losses). The amount of the dopant of the group 13 or 15, excluding nitrogen, may be higher than 0.001 wt. %.

In some embodiments, the doping material includes an element from the group 13 of the periodic table. In applications related to electronics, these materials can provide a p-doped type silicon layer. In particular embodiments, the target material comprises boron. In some embodiments, the doping material includes only one element from the group 13 (for example, only boron) at a meaningful amount, the amount of other doping materials (from different groups and/or even from group 13 itself) being negligible, provided that nitrogen is not considered part of the doping materials.

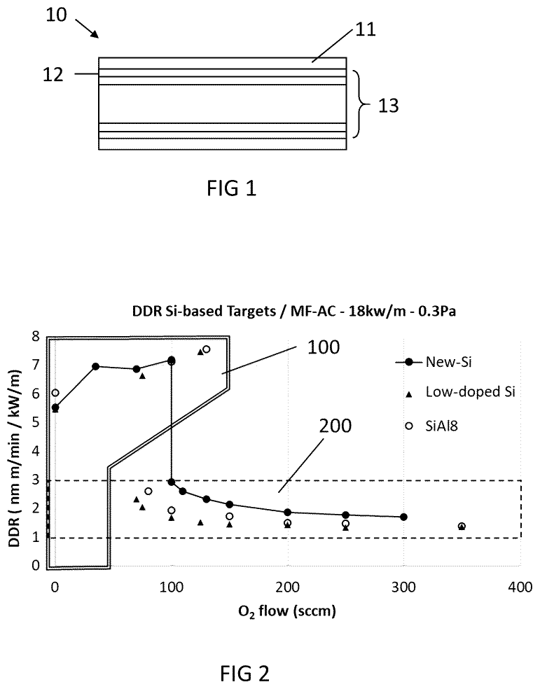

The target may be planar or cylindrical. The material for sputtering may be a single piece with a length of at least 500 mm, for example at least 800 mm, for example a cylinder of at least 500 mm or at least 800 mm of axial length, or a planar target with at least one dimension (e.g. length or width) or both dimensions being at least 500 mm or at least 800 mm. For example, FIG. 1 shows an elongated section view of a cylindrical target 10 with a single piece of target material 11 with lamellar structure. The target material 11 is provided by spraying directly on the carrier 13, optionally on a bonding layer 12 of the carrier 13. The bonding layer may comprise e.g. Cu, Ni or related metal alloys.

The target presents a porosity lower than 10%, typically being lower than 5%. For example, it may be 1% or higher. This allows easy dislodging of the particles from the target surface, as compared to a fully dense target material.

Existing pure Si targets typically present relatively high resistance, leading to a large voltage drop over the target material which causes power loses as resistive heating, increasing the risk of fracture as well as of charge build-up and subsequent arcing, and ultimately leading to a lower deposition rate. However, the targets of embodiments of the present invention present a resistivity lower than 1000 Ohm·cm, such as lower than 100 Ohm·cm, or even lower than 10 Ohm·cm, such as close to 1 Ohm·cm, however higher than 0.1 Ohm·cm, such that they do not require RF sputtering. Thanks to the light doping, the advantages of sputtering highly pure silicon are retained while improving the efficiency and power availability. It is enough to provide AC sputtering (for example at frequencies lower than 500 Hz), or even DC sputtering, allowing high power density loads on the pure Si target without surpassing critical stress levels that may cause material failure.

Patent application WO 2020/099438, in the paragraphs referencing FIG. 8 to FIG. 11, disclose different methods for measuring resistivity and resistance of a target. These methods can be used in the present invention.

In the following, deposition rate and related parameters will be discussed in order to properly establish comparisons between the target material of the present invention and existing target materials.

The thickness of the deposited layer is, in general, substantially proportionally to the exposure time to the deposition source, if the rest of process variables are considered constant. Deposition rate (DR) is obtained from the thickness of the deposited layer per exposure time unit (e.g. nm/min). This unit is often being used in small coaters, or taken as an average in batch coaters, while the substrates to be coated may undergo many cyclic deposition steps.

Dynamic deposition rate (DDR) is a parameter often used in in-line coaters, where the substrate, typically presenting a deposition area, is transported through one or more coater compartments, of which at least one comprises deposition sources. In the case of in-line coaters, the deposited layer thickness is inversely proportional to the transport speed along the deposition source. As such, layer thickness multiplied by transport speed is constant, and it is often expressed in nm·m/min (i.e. layer thickness in nm, multiplied by the substrate speed, in m/min).

The power level of the magnetron has an important influence in the deposition rate. In a first order approximation and if the rest of process variables are considered constant, sputter rate is linearly proportional to the applied power level. However, the applied power is applied on the target, and it distributes over the size of the target. This means that, in fact, sputter rate can be considered linearly proportional to the power density. Deposition rate, which is the rate at which particles deposit on the substrate, is always smaller than the sputter rate, and for a predetermined configuration (coating geometry, process conditions . . . ) it can be assumed proportional to the sputter rate. The amount of particles deposited on all the surfaces plus any amount of particles pumped away with the rest of the gas can be considered equal to the amount of particles sputtered.

For planar targets, this distribution of power over the target is often expressed as power level per target surface area (e.g. in W/cm²). However, it is more difficult to define an area for rotating cylindrical magnetrons.

Power density compensated dynamic deposition rate (PDC DDR) is based on a model which provides power density for rotating cylindrical magnetrons. The model implies that the sputtering occurs mainly in a line along the cylinder, as the surface area and plasma zone are typically very different. The PDC DDR can be obtained as the power level per target length (e.g. in kW/m). Under specific process conditions (e.g. metallic sputtering in pure Ar at a fixed pressure) it can be considered a (target) material constant.

The PDC DDR is typically used to allow comparing the deposition rates for samples of different coated layer thicknesses, and/or produced with multiple power densities, and/or at various glass transport speeds. PDC DDR is an easy and very flexible parameter for a first order calculation of layer thickness, substrate transport speed and/or power level for a given target composition and process condition.

For example, a given material has a PDC DDR of 6 (nm·m/min)/(kW/m). A single, 1-meter-long target may include such given material for sputtering. On such exemplary target, using a power level of about 20 kW, while the substrate is being transported in an in-line coater at a speed of 3 m/min transport speed, a layer with thickness about

$$( 6 nm \cdot m / min / kW / m ) \times ( 20 kW / 1 m ) / ( 3 m / min ) = 40 nm$$

can be expected on the substrate. More fundamentally, the PDC DDR value is inversely proportional to the average binding energy of atoms to the target surface, also referred to as the heat of sublimation.

PDC DDR allows comparing the material performance independent of the specific cylindrical target size, because in a first approximation, PDC DDR can be considered a material constant for a given process (e.g. depending on the amount of reactive gas that is added to the environment).

The dynamic deposition rates can be obtained for existing target materials using the definitions above. Under the same conditions, the dynamic deposition rates can be also obtained for target material in accordance with the present invention.

Several targets are obtained, both with existing target material and with the target material of the present invention. These samples are labelled as Low-doped Si and SiAl8 for existing target material, and “New-Si” for samples in accordance with the present invention, as it will be further explained.

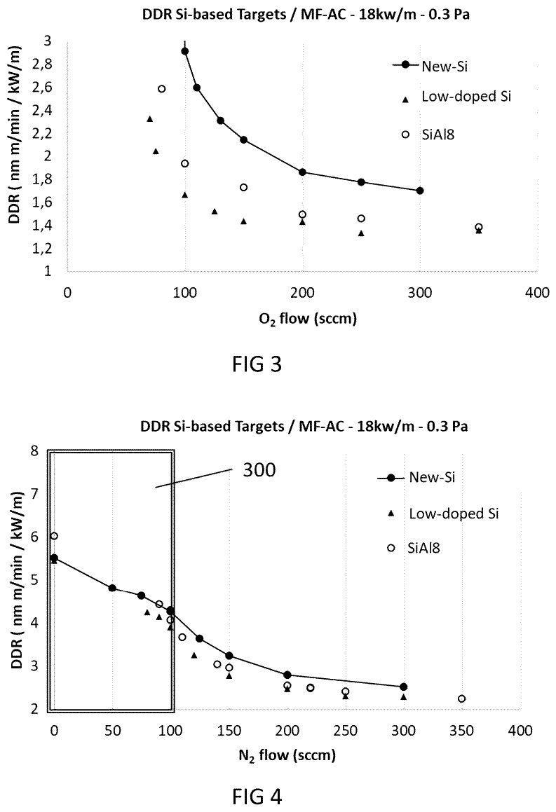

The results of the DDR are shown in FIG. 2 to FIG. 4 for different reactive species (oxygen and nitrogen) as a function of the flow in standard cubic centimetres per minute (sccm). It can be seen that, in general, target material in accordance with the present invention allows a DDR at least 10% higher than existing materials. FIG. 2 is focused on oxygen flow. FIG. 4 is focused on nitrogen flow. FIG. 3 shows the zoomed section indicated with a dashed rectangle 200 in FIG. 2.

The sputtering conditions were the same for all the targets and gasses: AC sputtering at a frequency of about 30 kHz with a power density of 18 kw/m and a pressure of 0.3 Pa. The environment may include a reactive gas, in the case of FIG. 2 and FIG. 3 the reactive gas is oxygen. It may include other gasses, such as discharge gas (typically a non-reactive gas, e.g. argon). The silicon material is sputtered onto a substrate, it reacts with the surrounding oxygen forming silicon oxide, which is considered transparent.

The area 100 surrounded by the double line shows the flow values at which it is possible to provide an opaque layer with high DDR. The target material may behave as a metallic target material with hysteresis behavior. This means that the reactive gas partial pressure presents hysteresis as a function of the oxygen flow into the chamber. At low oxygen flows, the process operates in so-called metallic mode and the deposited layers are metallic in character. The deposited layer under the conditions in this zone of the graph is mainly silicon, containing some traces of the reactive gas incorporated into the layer. As such, since silicon is not a transparent material, an opaque layer is observed. At higher oxygen flows, a compound layer is formed on the substrate, but also on the target surface. The process now operates in so-called poisoned mode and the deposited oxide layers are ceramic in character. The transition point from metallic to poisoned mode occurs at a different threshold oxygen flow than the reverse transition. A target in metallic sputtering mode sputters relatively fast compared to poison mode, so it needs more reactive gas to transition to poisoned. A target in poisoned mode (or poisoned target) sputters slower than in metallic mode, needing less reactive gas to transition back to metallic mode sputtering than the transition from metallic to poison mode. Also, it depends on the current state of the target surface and, to a lesser degree, on the composition of the target material, which explains the shape of the area 100. The dopant provides sufficient conductivity to the bulk of the target material to be sputtered in DC or AC. The hysteresis behavior in which a “metallic” target sputters faster and a “poisoned” target sputters slower is mainly related to the surface conditioning of the target. Of course, resistivity depends on the dopant level, so for lower amounts of dopant, the resistivity tends to increase, so a larger fraction of the applied power is lost in resistive heating. This causes a shift of the hysteresis transition zone towards lower reactive gas flows, as if a lower power level were applied. Indeed, at a lower power level, sputter cleaning of the target surface is reduced, and the same partial pressure of the reactive gas generates more surface poisoning.

FIG. 3 only focuses on the conditions for which a transparent silicon oxide layer is obtained, and where the change of DDR with oxygen flow is smooth, i.e. in the poisoned mode.

The materials used in the experiments include existing SiAl8 target material, which has a composition including 92 wt. % Si and 8 wt. % Al, and existing high purity Low-doped Si target material.

The target material in accordance with the present invention is labelled New-Si. In metallic sputtering conditions (where the oxygen flow is null), New-Si provides a deposition rate lower than for the existing SiAl target materials, because the resistance of the New-Si is higher. In pure metallic mode, the New-Si target performs similar to the high purity Low-doped Si target material. In the preferred process conditions, being the situation where the sputtering conditions provide sputtering in poisoned mode and the reactive gas flow is reduced to a point just before the flow value at which the target sputtering would return to metallic state, the DDR increases for the target material in accordance with the present invention. For example, at a flow of 100 sccm, the DDR of New-Si is almost twice the value for the DDR for the existing material Low-doped Si, as shown in FIG. 3.

It can be seen, taking into account the hysteresis behavior and as shown in FIG. 3, that the reactive gas working point at which the poisoned target switches back to metallic mode is higher for the New-Si target (around 100 sccm, see horizontal scale). This is in accordance with its higher DDR at that point (almost 3 DDR units, see vertical scale). Indeed, a reactive gas flow of 100 sccm oxygen is insufficient to keep the target in poisoned mode; the higher DDR and surface cleaning sputter effect may allow the New-Si target switching back to metallic mode. The state-of-the-art Si targets (SiAl8 and Low-doped Si) sputter slower in poisoned mode, so the surface cleaning effect is not enough to transition to metallic mode, and remain poisoned at 100 sccm: the flow needs to be further reduced e.g. to 80 sccm oxygen before the sputter cleaning becomes sufficiently high to balance the poisoning effect, allowing the target to return to metallic mode. This can be seen by the lower DDR as well. A fully transparent layer may be provided from any point of a poisoned target, because when the target is poisoned, then the deposited layer has most certainly a fully stoichiometric compound composition. Any working point of FIG. 3 may provide deposition of a transparent layer.

A second major reactive sputtering can be provided using nitrogen as the reactive species. Combined with a silicon target, silicon nitride layers can also be provided by sputter deposition in a reactive atmosphere containing nitrogen, as explained earlier, for architectural glass for instance for which large targets (larger than 800 mm for example) can be used.

FIG. 4 shows the dynamic deposition rates (DDR) of existing targets, compared to targets in accordance with the present invention, as a function of the nitrogen flow in standard cubic centimetres per minute (sccm). The area 300 surrounded by a double line shows the flow values at which it is possible to provide an opaque layer, which depends on the nitrogen flow. However, there is no hysteresis behaviour for deposition in nitrogen atmosphere (because in this case the sputter rate of the nitride is sufficiently high and closer to the sputter rate of the metallic mode). The transition of DDR with the nitrogen flow from deposition of opaque layer to deposition of transparent layer is smooth. However, the point at which there is transition is different for different materials. This is the case for the sample labelled as New-Si, where the transition occurs at slightly higher nitrogen flow than for the rest of target materials.

The sample labelled as SiAl8 is typically used in reactive sputtering with nitrogen to produce materials with predetermined or desired optical properties, because the optical index of aluminum nitride is similar to that of silicon nitride. While traditional Al-doped Si-target materials show stable sputtering, sputter rate is reduced, especially in higher flow conditions where the layer is transparent. The sample labelled as Low-doped Si also shows lower DDR in general (due to its lower conductivity).

On the other hand, the target material in accordance with the present invention shows higher DDR than other existing materials. The sample marked as New-Si shows generally higher DDR than existing target materials for flows typically used to provide transparent layers.

In summary, for reactive sputtering and at least for flow conditions which allow sputter deposition of transparent layers, targets in accordance with the present invention provide a DDR which is generally higher than for the existing materials.

The advantages of the present invention are not limited to the deposition rate. Using a sputter target material in accordance with the present invention enables the use of larger maximum sputter power than the power available for existing targets. Arcing is the limiting factor for SiAl8 and Low-doped Si. In the case of SiAl8, formation of Al₂O₃ islands may facilitate charge build-up and initiate arcing. For Low-doped Si, the lower doping results in a lower thermal conductivity and higher discharge voltage and higher arcing risk as a consequence.

This is shown in the following table.

TABLE I
Several characteristics of different thermally
sprayed 35″ targets are compared

| | SiAl8 | | Low-doped Si | | New-Si | |
|---|---|---|---|---|---|---|
| Technology | Thermal spray | | Thermal spray | | Thermal spray | |
| Porosity % | <5% | | <5% | | <5% | |
| doping | 80000 ppm of Al | | <10 ppm of B | | <300 ppm of B, | |
| (ppm) | | | | | Al or P | |
| resistivity | <0.01 | ohm · cm | >500 | ohm · cm | <1000 | ohm · cm |
| O/N (ppm) | <6000/<1000 | | <6000/<1000 | | <4000/<1000 | |
| Max pow | 30 | kW/m | 20 | kW/m | >30 | kW/m |
| (AC) | | | | | | |

| | | | |
|---|---|---|---|
| DDR in N2 | ~2.5 | 2.4 (↓−3%) | ~2.8 (↑10%) |
| DDR in O2 | ~1.7 | 1.4 (↓−17%) | ~2.1 (↑24%) |

The porosity in all the materials is comparable, under 5%. The oxygen and nitrogen levels are shown also. These impurity levels are expressed in ppm of mass fraction. In embodiments of the present invention, the oxygen and nitrogen content is lower as well as compared to the state-of-the-art materials. The maximum power that can be safely used during sputtering is noticeably higher in embodiments of the present invention compared to existing target materials. The percentages between brackets refer to the relative variation in DDR with respect to SiAl8 state-of-the-art targets. In general, the DDR for reactive sputtering of New-Si targets is at least 10% larger, as shown earlier. The rest of values can be found in the table.

Thus, the target material of embodiments of the present invention provides effective sputtering, allowing higher maximum sputter power, and at a high DDR compared to existing target materials. For example, this is the case for sputtering of layers with optical performance parameters, e.g. layers provided by reactive sputtering under controlled conditions adapted to provide transparent layers. This is the case for reactive sputtering in oxygen (for providing silicon oxide layers which present low refractive indices) and in nitrogen atmosphere (for providing silicon nitride layers, which present high refractive indices).

The targets in accordance with embodiments of the present invention can be used to provide layers suitable for electronic purposes, e.g. doped silicon. Since the target already includes an element from the group 13 or 15 of the periodic table, the end layer may comprise such elements which can provide p-type doping or n-type doping on a silicon layer, respectively. For example, a highly pure Si-target including less than 0.03 wt. % of an element from the group 13 of the table, such as boron, and only negligible amounts of other materials can provide a doped Si layer with p-type doping. In some embodiments, for example, the dopant material only includes negligible traces of aluminum. In the amount of impurities, the amount of nitrogen does not need to be included for the calculation of dopants. However the nitrogen and/or oxygen content in the target may be under 0.5 wt. %.

In some embodiments, the target is a cylindrical target that can withstand sputtering at a power density exceeding 30 kW AC/m, e.g. 35 kW AC/m or higher without delamination, cracking or generating any other material defect. It is noted that the AC power refers to providing power to a dual cathode system (having 2 targets), and the power density (per unit of length in these examples) refers to the length of a single target. As an example: having 30 kW AC/m on a dual (2 target) configuration of which each target has a length of 3 m would mean that a total power of 90 kW AC may be applied to this dual configuration.

In a further aspect, the present invention provides a method of sputtering a target in accordance with embodiments of the first aspect of the present invention. The method comprises, as shown in FIG. 5, providing 20 a target, for example in a deposition chamber, and sputtering 21, 22, 23 at a power density over 30 kW/m in AC, e.g. 35 kW/m in AC. It is an advantage that a high-power density load can be used without surpassing critical stress levels that may generate material failure. For example, no delamination, cracking or formation of other material defect occur using targets of the first aspect of the present invention at these power densities.

The method may comprise providing and sputtering a cylindrical target, which allows sputtering of large surfaces. The target can generate a sputtering 23 at a PDC DDR of 2 nm·m/min/(kW/m) in an optimized oxygen gas ambient, and/or over 2.5 nm·m/min/(kW/m) in an optimized nitrogen gas ambient, with a total working pressure in the range between 0.1 and 10 Pa. However, sputtering 22 can be provided in a non-reactive atmosphere.

In some embodiments, the PDC DDR is at least 1.5 nm·m/min/(kW/m) in metallic and in reactive mode (comprising oxygen and/or nitrogen).

In some embodiments, the sputtering parameters and conditions are adapted 24 in order to provide poisoned mode sputtering. This can be done as explained above, for example by bringing sputtering in an environment containing oxygen to a poisoned mode, and then gradually varying the conditions (e.g. reducing oxygen flow) until the DDR is maximized without a transition from poisoned mode to metallic mode.

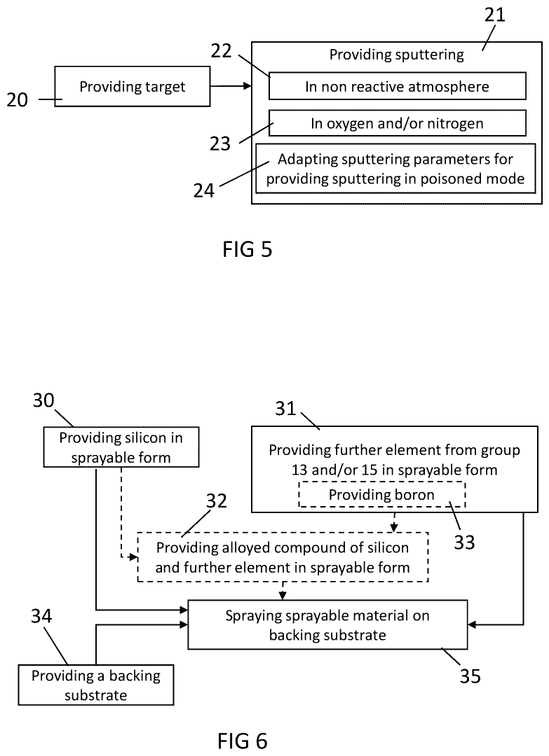

In a further aspect, the present invention provides a method of manufacturing a target in accordance with embodiments of the present invention. FIG. 6 shows a method in accordance with embodiments of the present invention, including optional steps. The method includes providing 30, 31 silicon and at least a further element from the group 13 or group 15 of the periodic table, and spraying 35 said elements on a carrier or backing substrate, thus providing a target with target material having a lamellar structure made up of splats. The spraying of elements is done in an amount such that a predetermined composition is provided, being at least 98 wt. % silicon and less than 0.03 wt. % of the further element, being a dopant element in the silicon. The amount of dopant excludes any amount of nitrogen that may be present in the target material.

In some embodiments, the materials can be provided 30, 31 as sprayable powder. For example, the different materials may be provided in separate powders that are mixed in a controlled way. In alternative embodiments, the material may be provided 32 as an alloyed powder in which the grains already contain the desired amount of Si and the further element (alloyed powder). Alternatively, the material in sprayable form may be a mixture of separate powders and of alloyed powders.

In some embodiments, the spraying conditions are tuned so that the amount of oxygen and nitrogen in the target material is under 0.5 wt. % (under 5000 ppm in mass fraction).

The carrier may be provided 34 as a planar or cylindrical carrier. In some embodiments, the spraying is done over a carrier so the final product is a single piece of target material in a carrier, which may be a rectangle or square of at least 500 mm long side, or a cylinder of at least 500 mm along the axis. For example the length may be 800 mm or even longer.

Spraying 35 the elements (e.g. powdered material) may comprise thermal spraying, for example flame spraying, etc.

Spraying 35 can be done with parameters such that the porosity of the obtained target material is at least 1%. The porosity may be lower than 10%, typically being lower than 5%. The porosity can be tuned by selection of spraying parameters such as particle size distribution of powder, particle speed during spraying, oxygen in the spraying environment, plasma flame temperature, etc. The spraying can be performed so that the end target material for sputtering may have a thickness of 4 mm or more on the target, thus providing lamellar structure throughout the thickness of the target material.

The target obtained by the method has a resistivity below 1000 ohm·cm, e.g. below 100 ohm·cm, e.g. at or below 10 ohm·cm, such as close to 1 ohm·cm, however typically higher than 0.1 Ohm·cm.

1.-13. (canceled)

14. A target for sputtering having target material for sputtering, the target material comprising a lamellar structure and a porosity of at least 1% and having a resistivity lower than 1000 ohm·cm, and further comprising silicon and at least a further element from the group 13 and/or the group 15 of the periodic table,
wherein the amount of silicon is at least 98 wt. %, and the amount of the at least a further element is higher than 0.001 wt. %. and lower than 0.03 wt. %,
wherein said amount does not include the amount of nitrogen if present.

15. The target of claim 14, wherein the at least a further element comprises an element from the group 13 of the periodic table.

16. The target of claim 14, wherein the at least a further element comprises boron.

17. The target of claim 14, further comprising oxygen and/or nitrogen in an amount lower than 0.5 wt. %.

18. The target of claim 14 comprising a single piece of target material for sputtering with a length of at least 500 mm.

19. The target of claim 14, wherein the target comprises a thickness of at least 4 mm of target material for sputtering.

20. The target of claim 14, wherein the resistivity of the target material is higher than 0.1 Ohm·cm

21. The target of claim 14, wherein the target is a cylindrical target.

22. A method for sputtering using a target of claim 14, comprising providing the target and providing sputtering using the target for depositing a layer comprising silicon at a power density higher than 30 kW/m in AC or DC sputtering.

23. The method of claim 22, wherein providing sputtering comprises providing sputtering in a non-reactive atmosphere or providing sputtering in a reactive atmosphere comprising oxygen and/or nitrogen.

24. The method of claim 23, further comprising providing a working pressure in the range between 0.1 Pa and 10 Pa.

25. A method for manufacturing a target, comprising providing silicon in sprayable form,
proving at least a further element from the group 13 or the group 15 of the periodic table in sprayable form,
providing a backing substrate, and
spraying the silicon and the at least further element on the backing substrate in amounts and with sputtering parameters configured such that a target is formed with a porosity of at least 1%, at least including at least 98 wt. % of silicon and more than 0.001 wt. % but less than 0.03 wt. % of at least a further element from the group 13 or the group 15 of the periodic table,
wherein the amount of the at least further element excludes the amount of nitrogen if present.

26. The method of claim 25, wherein spraying comprises thermal spraying.
